(19) United States
(12) Patent Application Publication
(10) Pub. No.: US 2024/0128942 A1
(43) Pub. Date: Apr. 18, 2024

(54) PIEZOELECTRIC TRANSDUCER PREPARATION METHOD AND PIEZOELECTRIC TRANSDUCER

(71) Applicant: SPECTRON (SHENZHEN) TECHNOLOGIES CO., LTD., Shenzhen (CN)

(72) Inventors: Songbin GONG, Shenzhen (CN); Gabriel VIDAL-ALVAREZ, Shenzhen (CN)

(21) Appl. No.: 18/278,075

(22) PCT Filed: May 31, 2021
(86) PCT No.: PCT/CN2021/097217

§ 371 Date: Aug. 21, 2023

(30) Foreign Application Priority Data
May 6, 2021 (CN) 202110489575.4

(51) Int. Cl. H03H 3/02; H03H 9/17

(52) U.S. Cl. CPC H03H 3/02; H03H 9/175; H03H 2003/025

(57) ABSTRACT

The present application relates to a piezoelectric transducer preparation method and a piezoelectric transducer. The method comprises: first, preparing a bottom acoustic reflection layer on a carrier wafer; then preparing a top acoustic reflection layer on a piezoelectric wafer; then combining the side of the bottom acoustic reflection layer that is away from the carrier wafer with the side of the top acoustic reflection layer that is away from the piezoelectric wafer; and finally, thinning the piezoelectric wafer to form a piezoelectric transducer. The carrier wafer performs a carrying function, a piezoelectric film formed by thinning the piezoelectric wafer can be excited by acoustic vibration, and the top acoustic reflection layer and the bottom acoustic reflection layer can limit the acoustic vibration, such that the resulting piezoelectric transducer can work at a high frequency. The piezoelectric transducer prepared by using the method has a specific stacking combination and a piezoelectric film, can excite and support a high-performance acoustic vibration mode, has a low inherent loss, and can obtain a higher capacitance per unit area while maintaining the unit area, such that a good working performance of the prepared piezoelectric transducer is achieved.

### CROSS-REFERENCE TO RELATED APPLICATIONS

This application is an U.S. national phase application under 35 U.S.C. § 371 based upon international patent application No. PCT/CN2021/097217, filed on May 31, 2021, which itself claims priority to Chinese patent application No. 2021104895754 filed on May 6, 2021. The contents of the above identified applications are hereby incorporated herein in their entireties by reference.

### TECHNICAL FIELD

The present disclosure relates to transducers, in particular to a method for preparing a piezoelectric transducer and a piezoelectric transducer.

### BACKGROUND

Transducers are devices that realize conversion between electrical energy and sound energy. As a specific type of transducers, piezoelectric transducers use the piezoelectric effect of certain crystalline materials to achieve the conversion between electrical energy and mechanical energy. Piezoelectric transducers are widely used due to their high electroacoustic efficiency, large power capacity, and their ability to be tailored in structure and shape to suit different applications.

Conventional piezoelectric transducers are based on bonding piezoelectric wafers to other carrier wafers, and most monocrystalline thin films on a silicon substrate are based on bonding piezoelectric wafers to carrier wafers (mostly silicon) directly or through a bonding interface layer. Such bonded carrier wafers can be used as piezoelectric transducers. However, the piezoelectric transducers prepared in this way have low maximum operating frequency, low capacitance density, low power threshold, and may have insuppressible spurious modes, resulting in poor performance of the piezoelectric transducers.

### SUMMARY

Accordingly, there is a need to provide a method for preparing a piezoelectric transducer and a piezoelectric transducer.

A method for preparing a piezoelectric transducer includes following steps of:
providing a carrier wafer and preparing a bottom acoustic reflection layer on the carrier wafer;
providing a piezoelectric wafer and preparing a top acoustic reflection layer on the piezoelectric wafer, wherein both the top acoustic reflection layer and the bottom acoustic reflection layer are configured to confine acoustic vibrations;
combining a side of the bottom acoustic reflection layer away from the carrier wafer and a side of the top acoustic reflection layer away from the piezoelectric wafer; and
thinning the piezoelectric wafer, thereby achieving the piezoelectric transducer.

A piezoelectric transducer is prepared by the aforementioned method.

In an embodiment, the step of providing the piezoelectric wafer and preparing the top acoustic reflection layer on the piezoelectric wafer includes substeps of:
providing the piezoelectric wafer, and preparing a bottom electrode layer on the piezoelectric wafer; and
preparing the top acoustic reflection layer covering the bottom electrode layer on the piezoelectric wafer.

In an embodiment, the bottom acoustic reflection layer includes one or more bottom high acoustic impedance layers and one or more bottom low acoustic impedance layers. The total number of the one or more bottom high acoustic impedance layers and the one or more bottom low acoustic impedance layers is an odd number. The step of providing the carrier wafer and preparing the bottom acoustic reflection layer on the carrier wafer includes substeps of:
providing the carrier wafer, and
alternately preparing the one or more bottom high acoustic impedance layers and the one or more bottom low acoustic impedance layers on one side of the carrier wafer.

In an embodiment, the top acoustic reflection layer includes a top low acoustic impedance layer, and the step of providing the piezoelectric wafer and preparing the top acoustic reflection layer on the piezoelectric wafer includes substeps of:
providing the piezoelectric wafer, and
preparing the top low acoustic impedance layer on the piezoelectric wafer.

In an embodiment, the top acoustic reflection layer includes one or more top low acoustic impedance layers and one or more top high acoustic impedance layers. The total number of the one or more top high acoustic impedance layers and the one or more top low acoustic impedance layers is an odd number. The step of providing the piezoelectric wafer and preparing the top acoustic reflection layer on the piezoelectric wafer includes substeps of:
providing a piezoelectric wafer, and
alternately preparing the one or more top low acoustic impedance layers and the one or more top high acoustic impedance layers on the piezoelectric wafer.

In an embodiment, in the bottom acoustic reflection layer, the farthest from the carrier wafer is a bottom low acoustic impedance layer, and in the top acoustic reflection layer, the farthest from the piezoelectric wafer is a top low acoustic impedance layer.

In an embodiment, in the bottom acoustic reflection layer, the farthest from the carrier wafer is a bottom high acoustic impedance layer, and in the top acoustic reflection layer, the farthest from the piezoelectric wafer is a top high acoustic impedance layer.

In an embodiment, after the step of providing the piezoelectric wafer and preparing the top acoustic reflection layer on the piezoelectric wafer, and prior to the step of combining the side of the bottom acoustic reflection layer away from the carrier wafer and the side of the top acoustic reflection layer away from the piezoelectric wafer, the method further includes a step of:
planarizing the side of the bottom acoustic reflection layer away from the carrier wafer and the side of the top acoustic reflection layer away from the piezoelectric wafer.

In an embodiment, the step of combining the side of the bottom acoustic reflection layer away from the carrier wafer with the side of the top acoustic reflection layer away from the piezoelectric wafer includes substeps of:
providing a bonding interface layer, and
combining the side of the bottom acoustic reflection layer away from the carrier wafer and the side of the top acoustic reflection layer away from the piezoelectric wafer through the bonding interface layer.

In an embodiment, the step of providing the piezoelectric wafer and preparing the top acoustic reflection layer on the piezoelectric wafer includes substeps of:
providing the piezoelectric wafer, implanting ions into the piezoelectric wafer, and
preparing the top acoustic reflection layer on the ion implanted piezoelectric wafer.

### BRIEF DESCRIPTION OF THE DRAWINGS

FIG. 1 is a flowchart of a method for preparing a piezoelectric transducer according to an embodiment.

FIG. 2 is a flowchart of a method for preparing a piezoelectric transducer according to another embodiment.

FIG. 3 is a flowchart of a method for preparing a piezoelectric transducer according to yet another embodiment.

FIG. 4 is a flowchart of a method for preparing a piezoelectric transducer according to yet another embodiment.

FIG. 5 is a flowchart of a method for preparing a piezoelectric transducer according to other embodiments.

FIG. 6 shows top views and cross-sectional views of piezoelectric transducers.

FIG. 7 is a schematic view of deposition and patterning of alternating low high acoustic impedance layers and high acoustic impedance layers on a carrier wafer.

FIG. 8 is a schematic view of deposition of a low acoustic impedance layer on a bottom of a piezoelectric wafer.

FIG. 9 is a schematic view of deposition of a bottom electrode layer and deposition of a low acoustic impedance layer on a piezoelectric wafer.

FIG. 10 is a schematic view of deposition and patterning of alternating low acoustic impedance layers and high acoustic impedance layers on a piezoelectric wafer.

FIG. 11 is a schematic view of planarization of an outermost layer on a carrier wafer and an outermost layer on a piezoelectric wafer.

FIG. 12 is a schematic view of a combination process.

FIG. 13 is a schematic view of thinning and polishing of a piezoelectric wafer.

FIG. 14 is a schematic view of ion implantation and slicing of a piezoelectric wafer.

### DETAILED DESCRIPTION OF THE EMBODIMENTS

In order to illustrate the purpose, technical solutions and advantages of the present disclosure clearer, the present disclosure will be described more fully through the following embodiments and in conjunction with the accompanying drawings. It should be understood that the specific embodiments described herein are only for explaining the present disclosure, and not intended to limit the present disclosure.

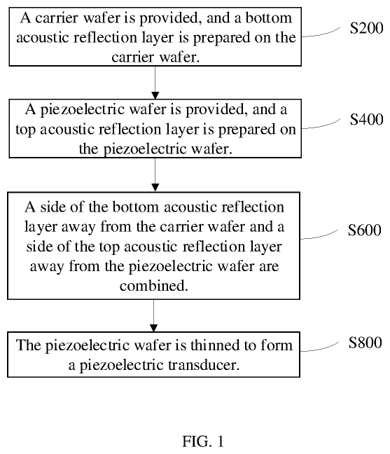

In an embodiment, referring to FIG. 1, a method for preparing a piezoelectric transducer is provided, which includes the following steps S200 to S800.

Step S200: a carrier wafer is provided, and a bottom acoustic reflection layer is prepared on the carrier wafer.

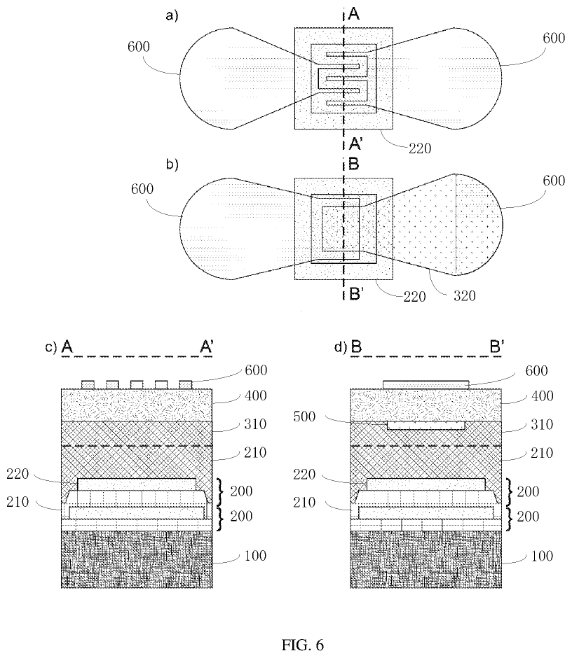

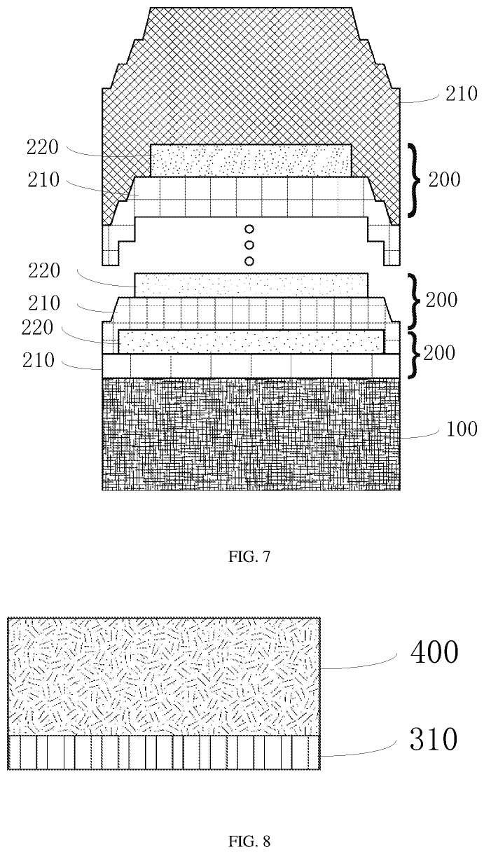

Referring to FIGS. 6 and 7, the carrier wafer 100 is a carrier device of the piezoelectric transducer. The carrier wafer 100 serves as a carrier of other structures in the piezoelectric transducer, and plays a role of carrying and fixing. The structure of the carrier wafer 100 is not exclusive. In the present embodiment, the carrier wafer 100 may be a wafer made of silicon, glass, sapphire, silicon carbide, quartz, or other materials. After the carrier wafer 100 is provided, the bottom acoustic reflection layer 200 is prepared on the carrier wafer 100, and the method for preparing the bottom acoustic reflection layer 200 is not exclusive. For example, a physical vapor deposition method, which has a high depositing speed, may be used to deposit the bottom acoustic reflection layer 200. Alternatively, an oxidation method or an epitaxial method may be used to form the bottom acoustic reflection layer 200 on the carrier wafer 100, so that the formed bottom acoustic reflection layer 200 has a high density and is relatively stable.

Further, after the bottom acoustic reflection layer 200 is prepared on the carrier wafer 100, the bottom acoustic reflection layer 200 may be patterned to form a specific shape as required by the piezoelectric transducer behavior. The method for patterning the bottom acoustic reflection layer 200 is not exclusive. In the present embodiment, the bottom acoustic reflection layer 200 may be patterned by photolithography, and the shape of the bottom acoustic reflection layer 200 may be designed as required to meet more requirements. The structure of the bottom acoustic reflection layer 200 is not exclusive, and may be a one-layer or multi-layer structure, as long as acoustic vibrations can be confined.

Step S400: a piezoelectric wafer is provided, and a top acoustic reflection layer is prepared on the piezoelectric wafer.

The structure of the piezoelectric wafer 400 is not exclusive, and can be any of the following doped versions: lithium niobate, lithium tantalate, aluminum nitride, quartz, etc. Referring to FIGS. 6 and 8 to 10, after the piezoelectric wafer 400 is provided, the top acoustic reflection layer 300 on the piezoelectric wafer 400 may be prepared by depositing or growing the top acoustic reflection layer 300 on the piezoelectric wafer 400. Further, after the top acoustic reflection layer 300 is prepared on the piezoelectric wafer 400, the top acoustic reflection layer 300 may also be patterned, so that the top acoustic reflection layer 300 forms a specific shape. The method for patterning the top acoustic reflection layer 300 is not exclusive. In the present embodiment, the top acoustic reflection layer 300 may be patterned by photolithography, and the shape of the top acoustic reflection layer 300 may be designed as required to meet more requirements. The structure of the top acoustic reflection layer 300 is not exclusive, it may be a one-layer or multi-layer structure, as long as acoustic vibrations can be confined. In addition, prior to preparing the top acoustic reflection layer 300, the piezoelectric wafer 400 may be subjected to ion implantation. In this way, the piezoelectric wafer 400 can be thinned by using film slicing and transfer technology in a subsequent thinning process. The process of ion implantation to the piezoelectric wafer 400 can be performed prior to the deposition and patterning of the top acoustic reflection layer 300. After the ion implantation, the piezoelectric wafer may be subjected to a series of heating, slicing, and polishing steps to leave a thin layer of piezoelectric material on the carrier wafer 100 to form a piezoelectric film.

Step S600: a side of the bottom acoustic reflection layer away from the carrier wafer and a side of the top acoustic reflection layer away from the piezoelectric wafer are combined.

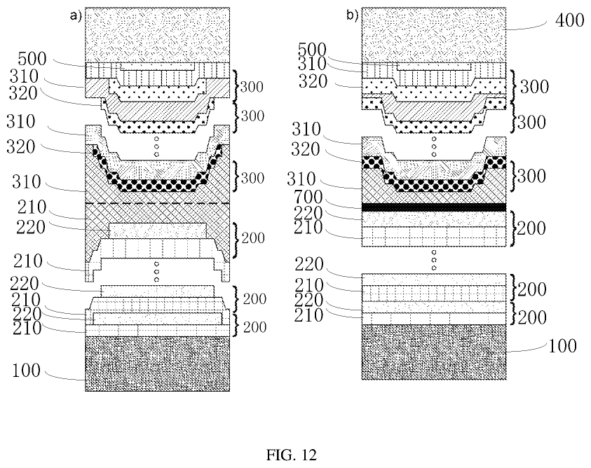

Referring to FIG. 6 or FIG. 12, after the bottom acoustic reflection layer 200 and the top acoustic reflection layer 300 are prepared, the side of the bottom acoustic reflection layer 200 away from the carrier wafer 100 and the side of the top acoustic reflection layer 300 away from the piezoelectric wafer 400 are combined. In this way, the bottom acoustic reflection layer 200 and the top acoustic reflection layer 300 are combined. The specific combining method is not exclusive. For example, the bottom acoustic reflection layer 200 and the top acoustic reflection layer 300 may be bonded together through van der Waals force, molecular force, or even atomic force, which ensures the working performance of the piezoelectric transducer.

Step S800: the piezoelectric wafer is thinned to achieve the piezoelectric transducer.

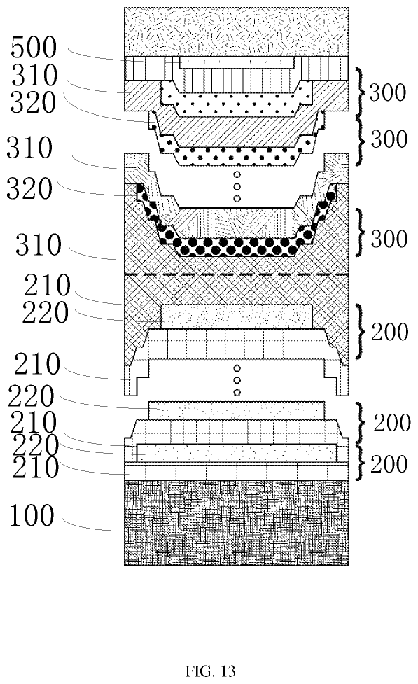

The piezoelectric wafer 400 is thinned after the side of the bottom acoustic reflection layer 200 away from the carrier wafer 100 and the side of the top acoustic reflection layer 300 away from the piezoelectric wafer 400 are combined. Referring to FIG. 13, the thickness of the piezoelectric wafer 400 reaches a desired value, so as to form the piezoelectric film. The piezoelectric transducer includes the carrier wafer 100, the bottom acoustic reflection layer 200, the top acoustic reflection layer 300, and the thinned piezoelectric wafer 400. The piezoelectric wafer 400, the top acoustic reflection layer 300, the bottom acoustic reflection layer 200, and the carrier wafer 100 are stacked one on another. The carrier wafer 100 serves as a carrier. The piezoelectric wafer 400 is thinned to form the piezoelectric film, which can be excited to generate acoustic vibrations. The top acoustic reflection layer 300 and the bottom acoustic reflection layer 200 can confine the acoustic vibrations, so that the obtained piezoelectric transducer can work at high frequencies. Since the piezoelectric transducer prepared by the method has a specific layer group including the piezoelectric film, it can excite and support high-performance acoustic vibration modes, has relatively low inherent loss, and can obtain relatively high capacitance per unit area while maintaining unit area, so that the manufactured piezoelectric transducer has good performance.

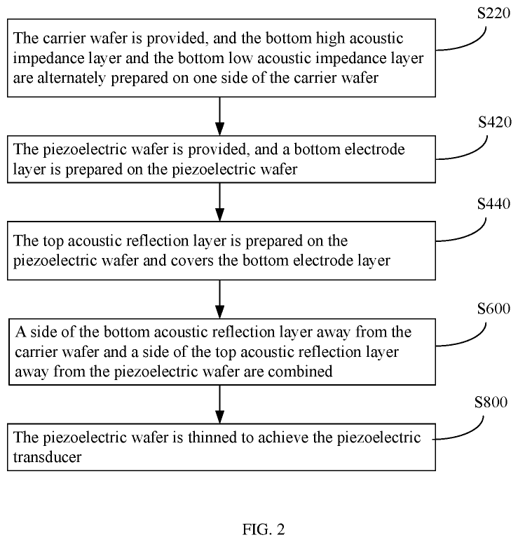

In an embodiment, referring to FIG. 2, step S400 includes step S420 and step S440.

Step S420: the piezoelectric wafer is provided, and a bottom electrode layer is prepared on the piezoelectric wafer 400.

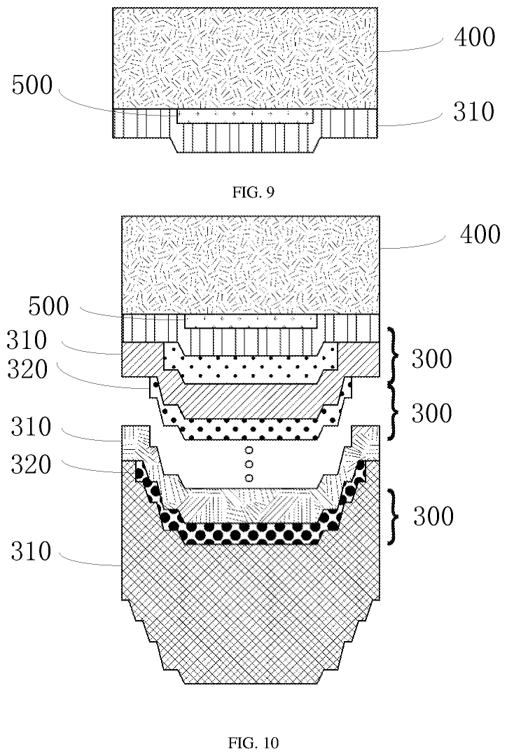

Specifically, the bottom electrode layer 500 is configured to transmit electrical signals. Typically, the bottom electrode layer 500 has a layered structure. Referring to FIG. 9, the bottom electrode layer 500 is deposited on the piezoelectric wafer 400 to form a bottom electrode of the piezoelectric transducer. Further, after the bottom electrode layer 500 is deposited on the piezoelectric wafer 400, the bottom electrode layer 500 can also be patterned to adjust the shape, the area, and the thickness of the bottom metal, etc., so as to meet specific requirements. The shape of the bottom electrode layer 500 is not exclusive and may be any geometry from square, rectangle, trapezoid or any polygon with n sides. The structure of the bottom electrode layer 500 is not exclusive and may be a metal layer made of Al, Pt, Cu, or an alloy of these metals, etc., which can be adjusted according to actual needs, as long as it can be achieved by those skilled in the art. The preparation of the bottom electrode layer 500 on the piezoelectric wafer 400 can change the direction of the electric field introduced by the electrode into the piezoelectric material, thus forming a new vibration mode, and improving the performance of the piezoelectric transducer. In addition, prior to preparing the bottom electrode layer 500, the piezoelectric wafer 400 may be subject to ion implantation. In this way, the piezoelectric wafer 400 can be thinned by using film slicing and transfer technology in a subsequent thinning process.

Step S440: the top acoustic reflection layer is prepared on the piezoelectric wafer and covers the bottom electrode layer.

After the bottom electrode layer 500 is prepared, referring to FIG. 9, the top acoustic reflection layer 300 is prepared on the piezoelectric wafer 400 and covers the bottom electrode layer 500. It should be understood that the bottom electrode layer 500 does not completely cover the piezoelectric wafer 400. A part of the top acoustic reflection layer 300 covers the surface of the bottom electrode layer 500 away from the piezoelectric wafer 400, and the other part of the top acoustic reflection layer 300 directly covers the piezoelectric wafer 400, so that the top acoustic reflection layer 300 is in contact with both the piezoelectric wafer 400 and the bottom electrode layer 500. Typically, the top acoustic reflection layer 300 is a layered structure and is disposed on the other side of the bottom electrode layer 500 to confine the acoustic vibrations. The type of the top acoustic reflection layer 300 is not exclusive, and the material of the top acoustic reflection layer 300 can be selected according to specific requirements. After the top acoustic reflection layer 300 is prepared on the side of the piezoelectric wafer 400 adjacent to the bottom electrode layer 500, the top acoustic reflection layer 300 may also be patterned, so that the shape and size of the top acoustic reflection layer 300 meet more requirements.

In an embodiment, the bottom acoustic reflection layer 200 includes a bottom high acoustic impedance layer 220 and a bottom low acoustic impedance layer 210. The sum of the number of bottom high acoustic impedance layers 220 and the number of the bottom low acoustic impedance layers 210 is an odd number. Referring to FIG. 2, step S200 includes step S220.

In the present embodiment, referring to FIG. 7, the bottom acoustic reflection layer 200 includes a bottom high acoustic impedance layer 220 and a bottom low acoustic impedance layer 210. The bottom high acoustic impedance layer 220 may be a layered structure made of aluminum nitride, tungsten, platinum, molybdenum, ruthenium or oxides thereof. The bottom low acoustic impedance layer 210 may be a layered structure made of silicon dioxide, spin glass, tellurium oxide, or other oxide families including other materials. One bottom high acoustic impedance layer 220 and one bottom low acoustic impedance layer 210 form a stack. In an example, the number of stack may be one, which has good manufacturability. Alternatively, one bottom acoustic reflection layer 200 may include two or more stacks, so as to improve the performance of the piezoelectric transducer. Further, the sum of the number of the bottom high acoustic impedance layers 220 and the number of the bottom low acoustic impedance layers 210 is an odd number, which means that besides the stack(s), the bottom acoustic reflection layer 200 further includes one end layer, which may be a bottom high acoustic impedance layer 220 or a bottom low acoustic impedance layer 210. The end layer is the layer farthest from the carrier wafer 100 in the bottom acoustic reflection layer 200. This layer provides a surface that is adapted to bond to another layer made of the same material, which is convenient for subsequent combination with the other layer.

Step S220: the carrier wafer is provided, and the bottom high acoustic impedance layer(s) and the bottom low acoustic impedance layer(s) are alternately prepared on one side of the carrier wafer.

When the bottom acoustic reflection layer 200 includes the bottom high acoustic impedance layer(s) 220 and the bottom low acoustic impedance layer(s) 210, after the carrier wafer 100 is provided, the bottom high acoustic impedance layer(s) 220 and the bottom low acoustic impedance layer(s) 210 are deposited layer by layer, alternately on one side of the wafer 100, so as to better confine the acoustic vibrations. In other embodiments, after preparing the alternating bottom high acoustic impedance layer(s) 220 and bottom low acoustic impedance layer(s) 210, this alternating layered structure can be transferred to the carrier wafer 100, as long as it can be achieved by those skilled in the art. The thicknesses of the bottom high acoustic impedance layer 220 and the bottom low acoustic impedance layer 210 are not exclusive. The bottom high acoustic impedance layer 220 and the bottom low acoustic impedance layer 210 may have different thicknesses, and the different thicknesses will result in more optimized performance of the manufactured piezoelectric transducers. The bottom high acoustic impedance layer 220 and the bottom low acoustic impedance layer 210 may have the same thickness, which is convenient for performing subsequent processes, and the thicknesses can be adjusted according to actual needs.

Further, after the bottom high acoustic impedance layer(s) 220 and bottom low acoustic impedance layer(s) 210 are alternately prepared on the side of the carrier wafer 100, either or both of the bottom high acoustic impedance layer(s) 220 and the bottom low acoustic impedance layer(s) 210 may be patterned, so that the bottom high acoustic impedance layer(s) 220 and/or the bottom low acoustic impedance layer(s) 210 form specific shape, so as to better meet requirements. The shape of the bottom high acoustic impedance layer(s) 220 and/or the bottom low acoustic impedance layer(s) 210 is not exclusive and can be adjusted according to actual needs.

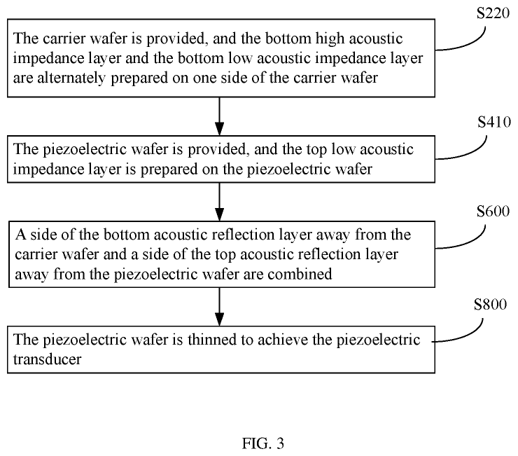

In an embodiment, referring to FIG. 3, the top acoustic reflection layer 300 includes a top low acoustic impedance layer 310. Step S400 includes step S410.

Step S410: the piezoelectric wafer is provided, and the top low acoustic impedance layer is prepared on the piezoelectric wafer.

The structure of the top acoustic reflection layer 300 is not exclusive. In the present embodiment, referring to FIG. 6, the top acoustic reflection layer 300 includes the top low acoustic impedance layer 310, which may be a layered structure made of silicon dioxide, spin glass, tellurium oxide, or other oxide families including other materials. When the top acoustic reflection layer 300 includes the top low acoustic impedance layer 310, one top low acoustic impedance layer 310 is provided. The top low acoustic impedance layer 310 is prepared on the piezoelectric wafer 400, which can be configured to confine acoustic vibrations. Further, in the embodiment that the bottom electrode layer 500 is prepared on one side of the piezoelectric wafer 400, the bottom electrode layer 500 does not completely cover the piezoelectric wafer 400. A part of the top low acoustic impedance layer 310 covers the surface of the bottom electrode layer 500 away from the piezoelectric wafer 400, and the other part of the top low acoustic impedance layer 310 directly covers the piezoelectric wafer 400, so that the top low acoustic impedance layer 310 is in contact with both the piezoelectric wafer 400 and the bottom electrode layer 500. The top low acoustic impedance layer 310 can cover the bottom electrode layer 500. Further, after the top low acoustic impedance layer 310 is prepared on the piezoelectric wafer 400, the top low acoustic impedance layer 310 may also be patterned, so that the top low acoustic impedance layer 310 has a specific shape to meet specific requirements.

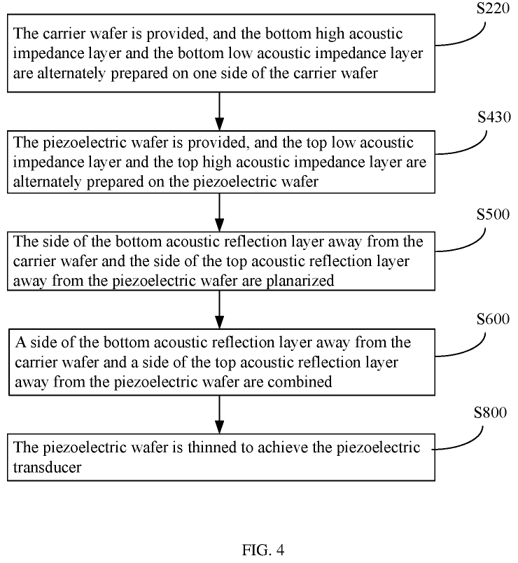

In an embodiment, the top acoustic reflection layer 300 includes not only the top low acoustic impedance layer 310 but also a top high acoustic impedance layer 320. The sum of the number of the top high acoustic impedance layer(s) 320 and the number of the top low acoustic impedance layer(s) 310 is an odd number. Referring to FIG. 4, step S400 includes step S430.

Step S430: the piezoelectric wafer is provided, and the top low acoustic impedance layer(s) and the top high acoustic impedance layer(s) are alternately prepared on the piezoelectric wafer.

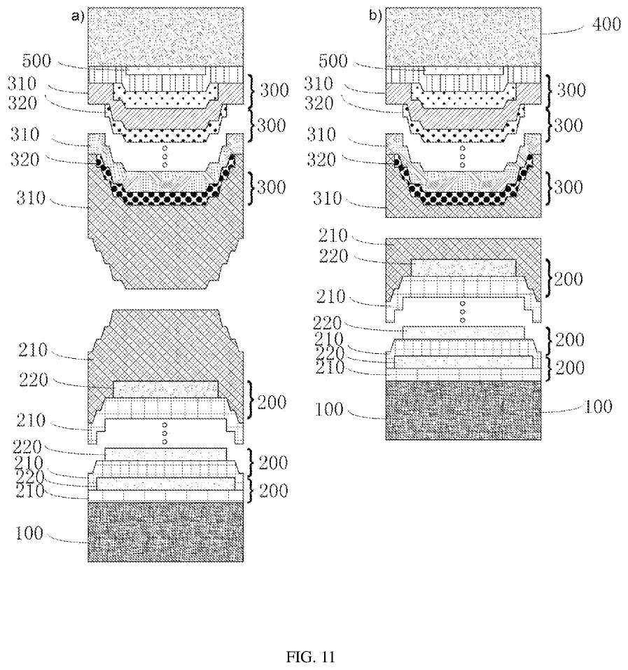

In the present embodiment, referring to FIGS. 11 to 14, in addition to the top low acoustic impedance layer 310, the top acoustic reflection layer 300 further includes a top high acoustic impedance layer 320. The top high acoustic impedance layer 320 may be a layered structure made of aluminum nitride, tungsten, platinum, molybdenum, ruthenium, or oxides thereof. One top high acoustic impedance layer 320 and one top low acoustic impedance layer 310 form a stack. In an example, the number of the stack can be one, which has good manufacturability. Alternatively, one top acoustic reflection layer 300 may include two or more stacks to improve the performance of the piezoelectric transducer. Further, the sum of the number of the top high acoustic impedance layers 320 and the number of the top low acoustic impedance layers 310 is an odd number, which means that besides the stack(s), the top acoustic reflection layer 300 further includes one end layer. This layer may be a top high acoustic impedance layer 320 or a top low acoustic impedance layer 310. The end layer is the layer furthest from the carrier wafer 100 in the top acoustic reflection layer 300.

Further, referring to FIG. 12a, the combination between the bottom acoustic reflection layer 200 and the top acoustic reflection layer 300 may occur at a certain interface between certain acoustic reflection layers, such that a relatively high strength can be achieved. In the subsequent process, the combined layers are not easy to peel off from each other. The position of the combination can be between the high impedance layers or between the low impedance acoustic layers, as long as it can be achievable by those skilled in the art. In addition, when the bottom electrode layer 500 has been prepared on the side of the piezoelectric wafer 400, it is typically a top low acoustic impedance layer 310 that directly covers the bottom electrode layer 500. A top high acoustic impedance layer 320 is prepared subsequently on the side of the top low acoustic impedance layer 310 away from the bottom electrode layer 500, so that the top low acoustic impedance layer(s) 310 and the top high acoustic impedance layer(s) 320 can be arranged alternately.

The top low acoustic impedance layer(s) 310 and the top high acoustic impedance layer(s) 320 may be deposited layer by layer on the piezoelectric wafer to form the alternately arranged top low acoustic impedance layer(s) 310 and top high acoustic impedance layer(s) 320. In other embodiments, after preparing the alternating top low acoustic impedance layer(s) 310 and top high acoustic impedance layer(s) 320, the alternating layered structure may be transferred to the piezoelectric wafer 400, as long as it can be achieved by those skilled in the art.

In an embodiment, in the bottom acoustic reflection layer 200, the farthest from the carrier wafer 100 is a bottom low acoustic impedance layer 210, and in the top acoustic reflection layer 300, the farthest from the piezoelectric wafer 400 is a top low acoustic impedance layer 310. Alternatively, in the bottom acoustic reflection layer 200, the farthest from the carrier wafer 100 is a bottom high acoustic impedance layer 220, and in the top acoustic reflection layer 300, the farthest from the piezoelectric wafer 400 is a top high acoustic impedance layer 320.

In the present embodiment, in the bottom acoustic reflection layer 200, the farthest from the carrier wafer 100 is a bottom low acoustic impedance layer 210, and in the top acoustic reflection layer 300, the farthest from the piezoelectric wafer 400 is a top low acoustic impedance layer 310. That is, the layer on the carrier wafer 100 and the layer on the piezoelectric wafer 400 that are to be combined together are both low acoustic impedance layers. Alternatively, in the bottom acoustic reflection layer 200, the farthest from the carrier wafer 100 is a bottom high acoustic impedance layer 220, and in the top acoustic reflection layer 300, the farthest from the piezoelectric wafer 400 is a top high acoustic impedance layer 320. That is, the layer on the carrier wafer 100 and the layer on the piezoelectric wafer 400 that are to be combined together are both high acoustic impedance layers. The outermost layer on the piezoelectric wafer 400 is made of the same material as the outermost layer on the carrier wafer 100, which can provide a good bonding interface and make the combination between the bottom acoustic reflection layer 200 and the top acoustic reflection layer 300 more stable.

In an embodiment, referring to FIG. 4, after step S400 and prior to step S600, the method for preparing the piezoelectric transducer further includes step S500.

Step S500: the side of the bottom acoustic reflection layer away from the carrier wafer and the side of the top acoustic reflection layer away from the piezoelectric wafer are planarized.

The planarization may include steps such as thinning and polishing. Referring to FIG. 11, prior to combining the bottom acoustic reflection layer 200 and the top acoustic reflection layer 300, the side of the bottom acoustic reflection layer 200 away from the carrier wafer 100 and the side of the top acoustic reflection layer 300 away from the piezoelectric wafer 400 are planarized, so as to provide a flat and smooth combination interface, so that the bottom acoustic reflection layer 200 and the top acoustic reflection layer 300 can combined more firmly. Further, if any of the carrier wafer 100, one or more layers of the bottom acoustic reflection layer 200, the piezoelectric wafer 400, and one or more layers of the top acoustic reflection layer 300 are patterned, each patterned structure are planarized prior to the combination step, so as to ensure the effectiveness of the interface combination.

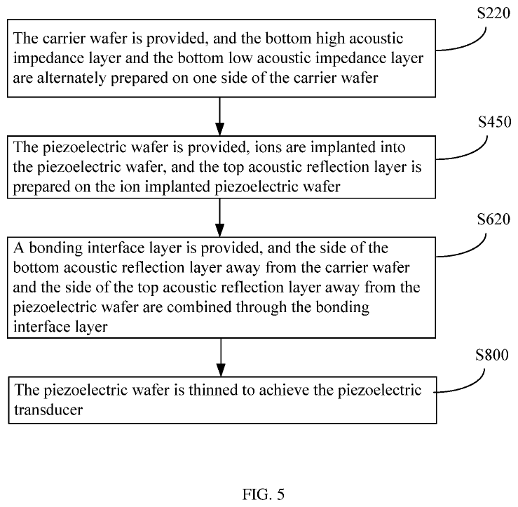

In an embodiment, referring to FIG. 5, step S600 includes step S620.

Step S620: a bonding interface layer is provided, and the side of the bottom acoustic reflection layer away from the carrier wafer and the side of the top acoustic reflection layer away from the piezoelectric wafer are combined through the bonding interface layer.

Specifically, referring to FIG. 12b, the bonding interface layer 700 is provided in the combination of the bottom acoustic reflection layer 200 and the top acoustic reflection layer 300. The side of the bottom acoustic reflection layer 200 away from the carrier wafer 100 and the side of top acoustic reflection layer 300 away from the piezoelectric wafer 400 are combined through the bonding interface layer 700. In an embodiment, the combination is by bonding of the bottom acoustic reflection layer 200 and the top acoustic reflection layer 300 together. The bonding can be such as thermo-compression bonding, surface activated direct bonding, etc. Other methods for bonding semiconductor wafers also can be used. The bonding can occur at a bottom portion or an upper portion, etc., of a certain acoustic reflection layer. When the layer in the bottom acoustic reflection layer 200 for combination and the layer in the top acoustic reflection layer 300 for combination are different in type, for example, one is a high acoustic reflection layer and the other is a low acoustic impedance layer, the two layers of different types can be combined through the bonding interface layer 700, so as to ensure a stable bonding. Generally, the bonding interface layer 700 is relatively thin, which will not have a great impact on the size of the piezoelectric transducer. The type of the bonding interface layer 700 is not exclusive, for example, it may be a silicon dioxide layer, etc. The bonding interface layer 700 may also be regarded as a part of the top acoustic reflection layer 300 or the bottom acoustic reflection layer 200.

In an embodiment, referring to FIG. 5, step S400 includes step S450.

Step S450: the piezoelectric wafer is provided, ions are implanted into the piezoelectric wafer, and the top acoustic reflection layer is prepared on the ion implanted piezoelectric wafer.

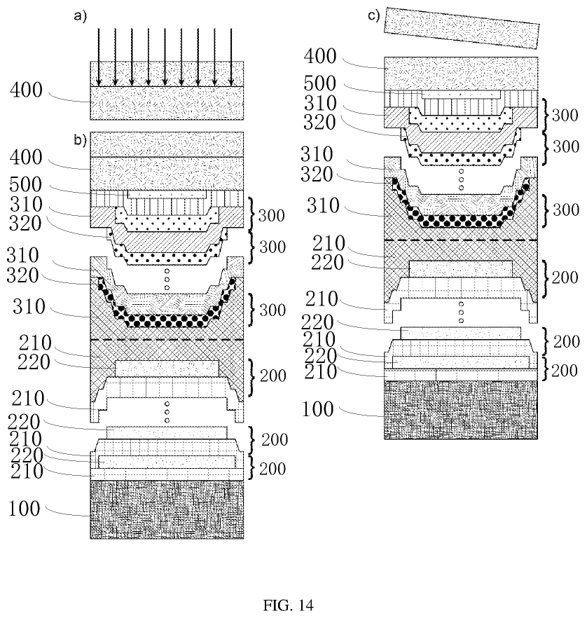

Referring to FIG. 14, prior to preparing the top acoustic reflection layer 300, the piezoelectric wafer 400 is subject to ion implantation. In this way, the piezoelectric wafer 400 can be thinned by using film slicing and transfer technology in the subsequent thinning process. The ion implantation to the piezoelectric wafer 400 is prior to the deposition and patterning of the top acoustic reflection layer 300. After the ion implantation, the bonding wafer may be subjected to a series of heating, slicing, and polishing steps to leave a thin layer of piezoelectric material on the carrier wafer 100 to form a piezoelectric film.

Optionally, the piezoelectric transducer further includes a top electrode layer 600. After the piezoelectric wafer 400 is thinned, the top electrode layer 600 is prepared on a side of the piezoelectric wafer 400 away from the top acoustic reflection layer 300. The top electrode layer 600 can be connected to a top electrode lead wire, connecting to other devices to achieve the function of the piezoelectric transducer.

In order to better understand the above embodiments, a detailed example will be given below. In the example, the bottom acoustic reflection layer 200 includes the low acoustic impedance layers and the high acoustic impedance layers, the top acoustic reflection layer 300 includes the low acoustic impedance layer or both the low acoustic impedance layers and the high acoustic impedance layers, and the bottom electrode layer 500 is a metal layer.

The method for preparing the piezoelectric transducer includes the process performed on the carrier wafer 100, the process performed on the piezoelectric wafer 400, and the process for bonding the wafers. Specifically, the process performed on the carrier wafer 100 includes the following steps. Referring to FIG. 7, the alternating low acoustic impedance layers and high acoustic impedance layers are deposited on the carrier wafer 100 and eventually patterned. These layers can be deposited by different physical vapor deposition methods, or they can be grown by oxidation or epitaxial methods. The high and low acoustic impedance layers can have different thicknesses and can be lithographically patterned into specific shapes as required by the piezoelectric transducer behavior. The layers forming the stack may be any number, starting from a minimum of 2. The stack needs to end in a layer (a high acoustic impedance layer or a low acoustic impedance layer), which provides a surface that is adapted to be bonded to another layer made of the same material. The carrier wafer 100 may be a wafer made of silicon, glass, sapphire, silicon carbide, quartz, or other materials. The low acoustic impedance layer may be made of silicon dioxide, spin glass, tellurium oxide, or other oxide families including other materials. The high acoustic impedance layer may be made of aluminum nitride, tungsten, platinum, molybdenum, ruthenium, or oxides thereof.

The process performed on the piezoelectric wafer 400 is as follows. Referring to FIG. 8, a thin low acoustic impedance layer is deposited or grown on the piezoelectric wafer 400, which is a bonding interface to an acoustic mirror formed on the carrier wafer. In another embodiment, referring to FIG. 9, a metal layer is deposited and eventually patterned on the piezoelectric wafer 400, and then a thin low acoustic impedance layer is deposited thereon. In other embodiments, referring to FIG. 10, one or more acoustic reflection layers may also be deposited or grown on the piezoelectric wafer 400. For example, one, two, or three pairs of alternating high acoustic impedance layers and low acoustic impedance layers may be deposited or grown on the piezoelectric wafer 400. The outermost layer on piezoelectric wafer 400 is made of the same material as the outermost layer on the carrier wafer 100, so as to provide a good bonding interface. The material of the piezoelectric wafer 400 may be any of the following doped versions: lithium niobate, lithium tantalate, aluminum nitride, and quartz.

The process performed to bond the piezoelectric wafer 400 and the carrier wafer 100 to obtain the piezoelectric film includes the following steps. In case of patterning of one or more layers on the carrier wafer 100 and/or on the piezoelectric wafer 400, referring to FIG. 11, prior to bonding, a planarization step is performed to each patterned wafer, so as to ensure a flat and smooth interface for wafer bonding. The bonding between the carrier wafer 300 and the piezoelectric wafer 400 may occur between: a. an interface in a certain acoustic reflection layer, either a high acoustic impedance layer or a low acoustic impedance layer (FIG. 12a); b. a bottom portion or an upper portion of an acoustic reflection layer. In this case, two sides of the carrier wafer 100 and the piezoelectric wafer 400 in contact with the bonding interface will have different acoustic impedance layers. In this embodiment, after the acoustic reflection layers have been formed, a thin material layer may be deposited on the two wafers to provide an appropriate bonding interface layer 700 (FIG. 12b). This ultra-thin layer of material for bonding may also be deposited in a portion of an acoustic reflection layer. Referring to FIG. 12, the piezoelectric wafer 400 and the carrier wafer 100 are bonded together through the established bonding interface. The bonding process can be any method based on thermo-compression bonding, surface activated direct bonding, or other methods to bond semiconductor wafers. Referring to FIG. 13, the piezoelectric wafer 400 is then thinned and polished to a desired thickness.

If the piezoelectric film is obtained by ion instead of mechanical polishing, the process performed to the piezoelectric wafer 400 needs to be slightly modified and the following steps are added. Referring to FIG. 14a, the process of ion implantation to the piezoelectric wafer 400 is required to be performed prior to the deposition and patterning of the metal electrode and the layer stack. The arrows in FIG. 14a indicate ion implantation. Referring to FIG. 14b, after ion implantation, the process follows as previously described, the bonded wafer is subjected to a series of heating, slicing, and polishing steps to form a thin layer of piezoelectric material remaining on top of the carrier wafer 100 (FIG. 14c). The material of the piezoelectric wafer 400 may be any of the following doped versions: lithium niobate, lithium tantalate, aluminum nitride, and quartz.

FIG. 6a and FIG. 6b show two structures of piezoelectric transducers prepared by the method of the present disclosure. In FIG. 6a a piezoelectric transducer is built on top of the patterned acoustic reflection layer stack. In FIG. 6b, a piezoelectric transducer is formed on top of the patterned acoustic reflection layers, having a thin metal layer in contact with the bottom surface of the piezoelectric layer.

A supplementary description for the drawings is as follows. FIG. 6 shows top views and cross-sectional views of the piezoelectric transducers including the patterned acoustic reflection layer stack, and in the case of b) and d), also incorporating a bottom electrode in direct contact with the piezoelectric layer by means of bonding two wafers. The examples shown use two pairs of low impedance layers and high impedance layers (in which only the high impedance layers are patterned) in the carrier wafer 100. The cross-section BB′ is used in all following figures to show the preparation process for the piezoelectric transducers. The dotted line in the figure represents the bonding interface in the examples (in these examples, the piezoelectric wafer 400 is not deposited with the low acoustic impedance layer and the high acoustic impedance layer prior to bonding). FIG. 7 is a schematic view of deposition and patterning of alternating low and high acoustic impedance layers on the carrier wafer 100. FIG. 8 is a schematic view of deposition of a low acoustic impedance layer on the bottom of the piezoelectric wafer 400. FIG. 9 is a schematic view of deposition and patterning a thin metal (the bottom electrode layer 500) on the piezoelectric wafer 400, and deposition of a low acoustic impedance layer on the piezoelectric wafer 400. FIG. 10 is a schematic view of deposition and patterning of alternating low acoustic impedance layers and high acoustic impedance layers on the piezoelectric wafer 400. FIG. 11 is a schematic view of planarization of the outermost layer on the carrier wafer 100 and the outermost layer on the piezoelectric wafer 400, so as to achieve bonding between the wafers. FIG. 12 is a schematic view of a bonding process, where (a) is for bonding the two wafers at an interface in an acoustic reflection layer, and (b) is for bonding at a bottom portion or an upper portion of an acoustic reflection layer. The dotted line in (a) indicates the bonding interface, and (b) includes an ultra-thin material layer for bonding, that is, the bonding interface layer 700. FIG. 13 is a schematic view of thinning and polishing the piezoelectric wafer 400. FIG. 14 is a schematic view of ion implantation and slicing of the piezoelectric wafer 400.

According to the aforementioned method for preparing the piezoelectric transducer, firstly, the carrier wafer 100 is provided, and the bottom acoustic reflection layer 200 is prepared on the carrier wafer 100, then the piezoelectric wafer 400 is provided, and the top acoustic reflection layer 300 is prepared on the piezoelectric wafer 400. The top acoustic reflection layer 300 and the bottom acoustic reflection layer 200 are configured to confine acoustic vibrations. Then, the side of the bottom acoustic reflection layer 200 away from the carrier wafer 100 and the side of the top acoustic reflection layer 300 away from the piezoelectric wafer 400 are combined, and finally the piezoelectric wafer 400 is thinned to achieve the piezoelectric transducer. In the piezoelectric transducer prepared by the piezoelectric transducer preparation method, the piezoelectric wafer 400, the top acoustic reflection layer 300, the bottom acoustic reflection layer 200, and the carrier wafer 100 are stacked one on another. The carrier wafer 100 serves as a carrier. The piezoelectric wafer 400 is thinned to form a piezoelectric film, which can be excited to vibrate acoustically. The top acoustic reflection layer 300 and the bottom acoustic reflection layer 200 can confine acoustic vibrations, so that the obtained piezoelectric transducer can operate at high frequencies. Since the piezoelectric transducer prepared by the method has a specific layer group including the piezoelectric film, it can excite and support high-performance acoustic vibration modes, has relatively low inherent loss, and can obtain relatively high capacitance per unit area while maintaining unit area, so that the manufactured piezoelectric transducer has good performance.

In an embodiment, the piezoelectric transducer is provided, which is prepared by the above-mentioned method.

According to the piezoelectric transducer, firstly, the carrier wafer 100 is provided, and the bottom acoustic reflection layer 200 is prepared on the carrier wafer 100, then the piezoelectric wafer 400 is provided, and the top acoustic reflection layer 300 is prepared on the piezoelectric wafer 400. The top acoustic reflection layer 300 and the bottom acoustic reflection layer 200 are configured to confine acoustic vibrations. Then, the side of the bottom acoustic reflection layer 200 away from the carrier wafer 100 and the side of the top acoustic reflection layer 300 away from the piezoelectric wafer 400 are combined, and finally the piezoelectric wafer 400 is thinned to achieve the piezoelectric transducer. In the piezoelectric transducer prepared by the piezoelectric transducer preparation method, the piezoelectric wafer 400, the top acoustic reflection layer 300, the bottom acoustic reflection layer 200, and the carrier wafer 100 are stacked one on another. The carrier wafer 100 serves as a carrier. The piezoelectric wafer 400 is thinned to form a piezoelectric film, which can be excited to vibrate acoustically. The top acoustic reflection layer 300 and the bottom acoustic reflection layer 200 can confine acoustic vibrations, so that the obtained piezoelectric transducer can operate at high frequencies. Since the piezoelectric transducer prepared by the method has a specific layer group including the piezoelectric film, it can excite and support high-performance acoustic vibration modes, has relatively low inherent loss, and can obtain relatively capacitance per unit area while maintaining unit area, so that the manufactured piezoelectric transducer has good performance.

The above-mentioned embodiments do not constitute a limitation on the protection scope of the technical solution. Any modifications, equivalent replacements and improvements made within the spirit and principles of the above-mentioned embodiments shall be included within the protection scope of this technical solution.

The foregoing descriptions are merely specific embodiments of the present disclosure but are not intended to limit the protection scope of the present disclosure. Any variation or replacement readily figured out by a person skilled in the art within the technical scope disclosed in the present disclosure shall all fall within the protection scope of the present disclosure.

1. A method for preparing a piezoelectric transducer, the method comprising:
providing a carrier wafer and preparing a bottom acoustic reflection layer on the carrier wafer;
providing a piezoelectric wafer and preparing a top acoustic reflection layer on the piezoelectric wafer, wherein both the top acoustic reflection layer and the bottom acoustic reflection layer are configured to confine acoustic vibrations;
combining a side of the bottom acoustic reflection layer away from the carrier wafer and a side of the top acoustic reflection layer away from the piezoelectric wafer; and
thinning the piezoelectric wafer, thereby achieving the piezoelectric transducer.

2. The method according to claim 1, wherein the step of providing the piezoelectric wafer and preparing the top acoustic reflection layer on the piezoelectric wafer comprises substeps of:
providing the piezoelectric wafer, and preparing a bottom electrode layer on the piezoelectric wafer; and
providing the top acoustic reflection layer covering the bottom electrode layer on the piezoelectric wafer.

3. The method according to claim 1, wherein the bottom acoustic reflection layer comprises one or more bottom high acoustic impedance layers and one or more bottom low acoustic impedance layers, the sum of the number of the one or more bottom high acoustic impedance layers and the number of the one or more bottom low acoustic impedance layers is an odd number, the step of providing the carrier wafer and preparing the bottom acoustic reflection layer on the carrier wafer comprises substeps of:
providing the carrier wafer, and
alternately preparing the one or more bottom high acoustic impedance layers and the one or more bottom low acoustic impedance layers on a side of the carrier wafer.

4. The method according to claim 3, wherein the top acoustic reflection layer comprises a top low acoustic impedance layer, and the step of providing the piezoelectric wafer and preparing the top acoustic reflection layer on the piezoelectric wafer comprises substeps of:
providing the piezoelectric wafer, and
preparing the top low acoustic impedance layer on the piezoelectric wafer.

5. The method according to claim 3, wherein the top acoustic reflection layer comprises one or more top low acoustic impedance layers and one or more top high acoustic impedance layers, the sum of the number of the top high acoustic impedance layers and the number of the top low acoustic impedance layer is an odd number, and the step of providing the piezoelectric wafer and preparing the top acoustic reflection layer on the piezoelectric wafer comprises substeps of:
providing a piezoelectric wafer, and
alternately preparing the one or more top low acoustic impedance layers and the one or more top high acoustic impedance layers on the piezoelectric wafer.

6. The method according to claim 5, wherein in the bottom acoustic reflection layer, the farthest from the carrier wafer is one bottom low acoustic impedance layer, and in the top acoustic reflection layer, the farthest from the piezoelectric wafer is one top low acoustic impedance layer; or
in the bottom acoustic reflection layer, the farthest from the carrier wafer is one bottom high acoustic impedance layer, and in the top acoustic reflection layer, the farthest from the piezoelectric wafer is one top high acoustic impedance layer.

7. The method according to claim 1, wherein after the step of providing the piezoelectric wafer and preparing the top acoustic reflection layer on the piezoelectric wafer, and prior to the step of combining the side of the bottom acoustic reflection layer away from the carrier wafer and the side of the top acoustic reflection layer away from the piezoelectric wafer, the method further comprises a step of:
planarizing the side of the bottom acoustic reflection layer away from the carrier wafer and the side of the top acoustic reflection layer away from the piezoelectric wafer.

8. The method according to claim 1, wherein the step of combining the side of the bottom acoustic reflection layer away from the carrier wafer and the side of the top acoustic reflection layer away from the piezoelectric wafer comprises substeps of:
providing a bonding interface layer, and
combining the side of the bottom acoustic reflection layer away from the carrier wafer and the side of the top acoustic reflection layer away from the piezoelectric wafer through the bonding interface layer.

9. The method according to claim 1, wherein the step of providing the piezoelectric wafer and preparing the top acoustic reflection layer on the piezoelectric wafer comprises substeps of:
providing the piezoelectric wafer, implanting ions into the piezoelectric wafer, and
preparing the top acoustic reflection layer on the ion implanted piezoelectric wafer.

10. A piezoelectric transducer, prepared according to the method of claim 1.
